(19) United States
(12) Patent Application Publication
(10) Pub. No.: US 2026/0212554 A1
(43) Pub. Date: Jul. 23, 2026

(54) GENERATING DESIGN LAYOUTS WITH DIFFERENT ASPECT RATIOS USING A CUSTOM GENERATIVE TRANSFORMER MODEL

(71) Applicant: Adobe Inc., San Jose, CA (US)

(72) Inventors: Kaushal Kishore, New Delhi (IN); Nitesh Dodeja, Delhi (IN); Vineet Batra, Pitam Pura (IN)

(21) Appl. No.: 19/028,258

(22) Filed: Jan. 17, 2025

(51) Int. Cl. G06T 11/60; G06N 3/045; G06N 3/09

(52) U.S. Cl. CPC G06T 11/60; G06N 3/045; G06N 3/09; G06T 2200/24

(57) ABSTRACT

The present disclosure relates to systems, non-transitory computer-readable media, and methods for generating modified digital designs in a target aspect ratio. In some embodiments, the disclosed systems utilize a transformer neural network to encode, from a digital design in an initial aspect ratio depicting one or more design elements, an input feature representation including tokenizations of the one or more design elements, an initial aspect ratio token, and a target aspect ratio token. In some embodiments, the disclosed systems utilize a transformer neural network to transform the input feature representation into an output feature representation including a modified tokenization of the one or more design elements according to the target aspect ratio. In some embodiments, the disclosed systems generate a modified digital design depicting one or more design elements according to the target aspect ratio utilizing the transformer neural network based on the output feature representation.

### BACKGROUND

A key challenge in generating digital designs is the difficulty of adapting a given layout to a different aspect ratio while preserving the visual harmony, balance, and aesthetic integrity of the original digital design. Reconfiguring digital design layouts requires dynamically adjusting element placements to ensure a cohesive presentation across varying aspect ratios. In many existing systems, this adaptation process is manual, requiring significant time and effort for each layout variation for the digital design. Although some generative artificial intelligence (AI) approaches offer a measure of automation to layout generation, such approaches often degrade or warp design elements when modifying aspect ratios. Thus, despite advancements in reconfiguring layouts, existing systems exhibit a number of drawbacks or disadvantages in generating reconfigured layouts for digital designs.

### SUMMARY

This disclosure describes one or more embodiments of systems, methods, and non-transitory computer readable media that solve one or more of the foregoing or other problems in the art by generating modified digital designs utilizing a transformer neural network, where the modified digital designs depict design elements in a target aspect ratio. In some embodiments, the disclosed systems utilize the transformer neural network to decompose a digital design into one or more discrete design elements. In one or more embodiments, the disclosed systems encode an input feature representation from the digital design, with the input feature representation including a tokenization of the one or more design elements, an initial aspect ratio token for the aspect ratio of the digital design, and a target aspect ratio token. In some embodiments, the disclosed systems utilize the transformer neural network to transform the input feature representation into an output feature representation including a modified tokenization of the one or more design elements according to the target aspect ratio. In one or more embodiments, the disclosed systems utilize the transformer neural network to generate a modified digital design formatted according to the target aspect ratio depicting the one or more design elements.

### BRIEF DESCRIPTION OF THE DRAWINGS

The disclosure describes one or more embodiments of the invention with additional specificity and detail by referencing the accompanying figures. The following paragraphs briefly describe those figures.

FIG. 1 illustrates a diagram of an environment in which a design reformatting system operates in accordance with one or more embodiments.

FIG. 2 illustrates a diagram of an overview of the design reformatting system generating a modified digital design in accordance with one or more embodiments.

FIG. 3 illustrates a diagram of decomposing a digital design in accordance with one or more embodiments.

FIG. 4 illustrates a diagram of generating an input feature representation for a digital design in accordance with one or more embodiments.

FIG. 5 illustrates a diagram of transforming the input feature representation into an output feature representation in accordance with one or more embodiments.

FIG. 6 illustrates a diagram of generating a modified digital design from the output feature representation in accordance with one or more embodiments.

FIGS. 7A-7B illustrate diagrams of training the transformer neural network in accordance with one or more embodiments.

FIGS. 8A-8B illustrate example images of transforming the layout of a digital design in accordance with one or more embodiments.

FIG. 9 illustrates an example schematic diagram of a design reformatting system in accordance with one or more embodiments.

FIG. 10 illustrates an example flowchart of a series of acts for generating a modified digital design in a target aspect ratio in accordance with one or more embodiments.

FIG. 11 illustrates a block diagram of an example computing device in accordance with one or more embodiments.

### DETAILED DESCRIPTION

This disclosure describes one or more embodiments of a design reformatting system that generates reformatted digital designs according to a target aspect ratio. For example, the design reformatting system decomposes a digital design into one or more design elements. In some embodiments, the design reformatting system utilizes a transformer neural network to generate an input feature representation by tokenizing the one or more design elements and by tokenizing an initial aspect ratio and a target aspect ratio. In one or more embodiments, the design reformatting system utilizes the transformer neural network to transform the input feature representation into an output feature representation by modifying the design element tokenizations (which encode element characteristics for the elements) for the output feature representation according to the target aspect ratio. In some embodiments, the design reformatting system utilizes the transformer neural network to generate a modified digital design depicting the design elements arranged and sized according to the target aspect ratio.

In one or more embodiments, the design reformatting system decomposes a digital design into one or more design elements. For example, the design reformatting system identifies one or more design elements within the digital design. In some cases, the design reformatting system classifies, categorizes, or labels design elements as text design elements or image design elements. In one or more embodiments, the design reformatting system decomposes the one or more design elements by determining, extracting, or defining a set of characteristics for the design elements. Such characteristics include, in some cases, the category (text design element or image design element), the coordinates of a design element (e.g., in x-pixel and y-pixel values), the width (e.g., in pixels), and the height (e.g., in pixels) of the design element.

In one or more embodiments, the design reformatting system utilizes the transformer neural network to generate an input feature representation. For example, the design reformatting system generates the input feature representation by tokenizing the aspect ratio of the digital design, by tokenizing the decomposed design elements (thus encoding their respective characteristics), and by tokenizing a specified target aspect ratio. In some embodiments, the design reformatting system utilizes the transformer neural network to transform the input feature representation to an output feature representation. For instance, the design reformatting system converts the design element tokens according to a format constraint (defining a layout sequence of tokens) and a category constraint (defining a number of design elements in each category, matching the number in the output sequence to the number in the input sequence). In one or more embodiments, the design reformatting system utilizes the transformer neural network to generate a modified digital design from the output feature representation, with the placement of the design elements in the modified digital design defined according to the modified design element tokenizations.

In one or more embodiments, the design reformatting system trains the transformer neural network to generate modified digital designs. In some embodiments, the design reformatting system performs a pretraining process to train the transformer neural network by feeding a concatenated feature representation into the transformer neural network. In particular, the design reformatting system performs the pretraining process to train the transformer neural network by feeding the transformer neural network two random layout sequences concatenated to train the transformer neural network to understand the relationship and structure of the layout sequences.

In one or more embodiments, the design reformatting system performs a fine-tuning process to train the transformer neural network by using a sample input feature representation as input and a sample output feature representation as output (where the input and output representations are from a custom layout dataset). In some embodiments, the design reformatting system trains the transformer neural network using the transformer neural network to generate a predicted sample output feature representation, compare the predicted output feature representation to a ground-truth sample output feature representation, generate a loss value, and modify parameters of the transformer neural network according to the loss value.

As suggested above, existing systems exhibit drawbacks or deficiencies in modifying digital designs for new aspect ratios. Although conventional systems generate modified digital designs in specified aspect ratios to an extent, such systems have a number of problems or inadequacies in relation to accuracy and flexibility. For instance, conventional systems inaccurately generate modified digital designs that fail to preserve the design integrity and aesthetic quality of the original digital design. To illustrate, some conventional systems, when generating modified digital designs, generate modified digital designs that place the design elements in incorrect locations and/or with warped or distorted shapes and sizes within the layout of the modified digital design. Further, some conventional systems generate modified digital designs that place the design elements in overlapping locations within the layout of the modified digital design.

Additionally, conventional systems are inflexible. For instance, certain conventional systems are limited to generating modified digital designs having a limited set of predefined aspect ratios. Indeed, some existing systems are rigidly fixed to a small set of aspect ratios and often cannot adapt the aspect ratio modification to maintain aesthetics of internal design elements, instead limiting the aspect ratio modification process to the boundaries of the design as a whole.

As suggested, embodiments of the design reformatting system provide several advantages and benefits over conventional systems. For example, the design reformatting system improves accuracy and reliability over prior systems. By generating and converting an input feature representation including tokenizations of the design elements (along with the initial and target aspect ratios) using the described transformer neural network, the design reformatting system accurately and reliably defines the location and layout of the design elements for new aspect ratios. Further, unlike prior systems that warp and distort designs when changing aspect ratios, by utilizing the transformer neural network to generate a modified digital design from an output feature representation, the design reformatting system generates the modified digital design in the target aspect ratio while preserving the design integrity and aesthetic quality of the original design element.

The design reformatting system also improves flexibility relative to conventional systems. Specifically, by generating input feature representations encoding the location of design elements and the initial aspect ratio and the target aspect ratio, the design reformatting system flexibly adapts modified digital designs to multiple target aspect ratios. Further, by generating an input feature representation capable of conversion into multiple output feature representations, the design reformatting system thus generates multiple modified digital designs from the same original digital design, extending the adaptation of aspect ratio changes to internal design elements, including their sizes and locations.

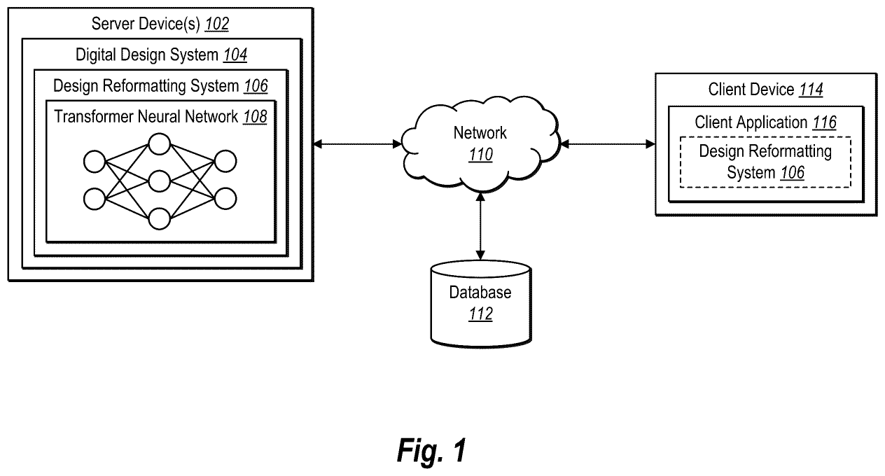

Additional detail regarding the design reformatting system 106 will now be provided with reference to the figures. For example, FIG. 1 illustrates a schematic diagram of an example system environment for implementing a design reformatting system 106 in accordance with one or more embodiments. An overview of the design reformatting system 106 is described in relation to FIG. 1. Thereafter, a more detailed description of the components and processes of the design reformatting system 106 is provided in relation to the subsequent figures.

As shown, the environment includes server device(s) 102, a database 112, a network 110, and a client device 114. Each of the components of the environment communicate via the network 110, and the network 110 is any suitable network over which computing devices communicate.

As mentioned, the environment includes a client device 114. The client device 114 is one of a variety of computing devices, including a smartphone, a tablet, a smart television, a desktop computer, a laptop computer, a virtual reality device, an augmented reality device, or another computing device. The client device 114 communicates with the server device(s) 102 via the network 110. For example, the client device 114 provides information to server device(s) 102 indicating client device interactions (e.g., selecting a digital design or a target aspect ratio) and receives information from the server device(s) 102 (e.g., a modified digital design). Thus, in some cases, the design reformatting system 106 on the server device(s) 102 provides and receives information based on client device interaction via the client device 114.

As shown in FIG. 1, the client device 114 includes a client application 116. In particular, the client application 116 is a web application, a native application installed on the client device 114 (e.g., a mobile application, a desktop application, etc.), or a cloud-based application where all or part of the functionality is performed by the server device(s) 102. Based on instructions from the client application 116, the client device 114 presents or displays information to a user. For example, the client device 114 presents modified digital designs according to instructions or display data generated and provided by the design reformatting system 106 and interpreted by a processor (e.g., a graphics processor) and/or renderer on the client device 114. In some cases, the client device 114 includes a version of the design reformatting system 106.

As illustrated in FIG. 1, the environment includes the server device(s) 102. The server device(s) 102 generates, tracks, stores, processes, receives, and transmits electronic data, such as digital designs, initial aspect ratio, target aspect ratio, and training information. The server device(s) 102, for example, receives data from the client device 114 in the form of an indication of a client device interaction (e.g., a digital design or a target aspect ratio) to generate a modified digital design from the client device interaction. In response, the server device(s) 102 transmits data to the client device 114 to display or present a modified digital design based on the client device interaction.

In some embodiments, the server device(s) 102 communicates with the client device 114 to transmit and/or receive data via the network 110, including client device interactions, digital designs, and/or other data. In some embodiments, the server device(s) 102 comprises a distributed server where the server device(s) 102 includes a number of server devices distributed across the network 110 and located in different physical locations. The server device(s) 102 comprise a content server, an application server, a communication server, a content editing server, a web-hosting server, a multidimensional server, and/or a machine learning server. The server device(s) further access and utilize the database 112 to store and retrieve information such as digital designs, target aspect ratios, and all or part of the transformer neural network 108.

In some cases, a transformer neural network refers to a neural network architecture designed to process sequential data by focusing on the relationships between elements, regardless of the positions of the elements in the sequence. In particular, a transformer neural network assigns varying levels of importance to different parts of input data to enable context-aware processing. For example, a transformer neural network includes multiple layers, with each layer including self-attention modules and feed-forward network, with the transformer neural network using positional encodings to retain order information for tasks like language modeling and machine translation.

Relatedly, in some embodiments, a neural network includes or refers to a machine learning model that can be trained and/or tuned based on inputs to determine classifications, scores, or approximate unknown functions. For example, a neural network includes a model of interconnected artificial neurons (e.g., organized in layers) that communicate and learn to approximate complex functions and generate outputs (e.g., modified digital designs in one or more target aspect ratios) based on a plurality of inputs provided to the neural network. In some cases, a neural network refers to an algorithm (or a set of algorithms) that implements deep learning techniques to model high-level abstractions in data. A neural network can include various layers such as an input layer, one or more hidden layers, and an output layer that each perform tasks for processing data. For example, a neural network can include a deep neural network, a convolutional neural network, a recurrent neural network (e.g., an LSTM), a graph neural network, or a large language model.

As further shown in FIG. 1, the server device(s) 102 also includes the design reformatting system 106 as part of a digital design system 104. For example, in one or more implementations, the digital design system 104 is able to store, generate, modify, edit, enhance, provide, distribute, and/or share digital designs. For example, the digital design system 104 provides tools for the client device 114, via the client application 116, to generate modified digital designs using the transformer neural network 108.

In one or more embodiments, the server device(s) 102 includes all, or a portion of, the design reformatting system 106. For example, the design reformatting system 106 operates on the server device(s) 102 to generate modified digital designs. In some cases, the design reformatting system utilizes, locally on the server device(s) 102 or from another network location (e.g., the database 112), the transformer neural network 108 to generate a modified digital design.

In certain cases, the client device 114 includes all or part of the design reformatting system 106. For example, the client device 114 generates, obtains (e.g., downloads), or utilizes one or more aspects of the design reformatting system 106 from the server device(s) 102. Indeed, in some implementations, as illustrated in FIG. 1, the design reformatting system 106 is located in whole or in part on the client device 114. For example, the design reformatting system 106 includes a web hosting application that allows the client device 114 to interact with the server device(s) 102. To illustrate, in one or more implementations, the client device 114 accesses a web page supported an/or hosted by the server device(s) 102.

In one or more embodiments, the client device 114 and the server device(s) 102 work together to implement the design reformatting system 106. For example, in some embodiments, the server device(s) 102 train the transformer neural network 108 and provide the transformer neural network 108 to the client device 114 for implementation. In some embodiments, the client device 114 attaches a digital design, the server device(s) 102 generates the modified digital design, and the client device 114 presents the modified digital design. Furthermore, in some implementations, the client device 114 assists in generating the modified digital design.

Although FIG. 1 illustrates a particular arrangement of the environment, in some embodiments, the environment has a different arrangement of components and/or may have a different number or set of components altogether. For instance, as mentioned, the design reformatting system 106 is implemented by (e.g., located entirely or in part on) the client device 114. In addition, in one or more embodiments, the client device 114 communicates directly with the design reformatting system 106, bypassing the network 110. Further, in some embodiments, the transformer neural network 108 includes one or more components stored in the database 112, maintained by the server device(s) 102, the client device 114, or a third-party device.

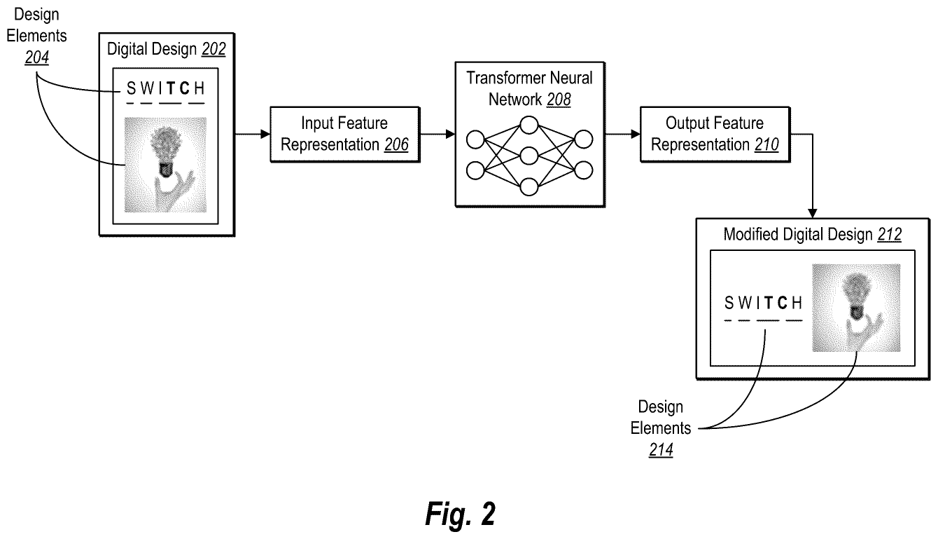

As mentioned, in one or more embodiments, the design reformatting system 106 generates a modified digital design utilizing a transformer neural network. FIG. 2 illustrates an overview of generating a modified digital design from an initial digital design by utilizing a transformer neural network to transform an input feature representation into an output feature representation in accordance with one or more embodiments. Additional detail regarding the various acts and processes mentioned with respect to FIG. 2 is provided thereafter with respect to subsequent figures.

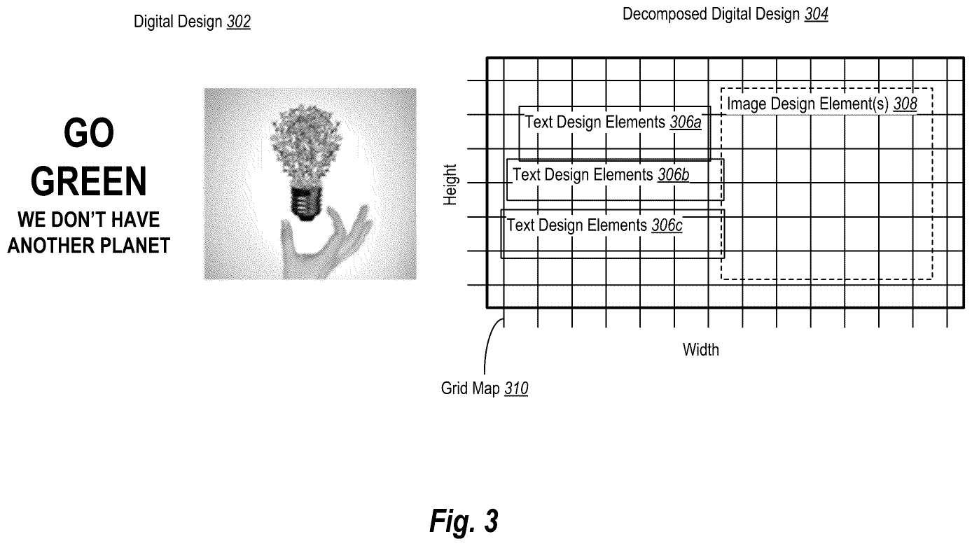

As illustrated in FIG. 2, the design reformatting system 106 receives a digital design 202. In particular, the design reformatting system 106 receives the digital design 202 as an input from a client device (e.g., the client device 114), such as an upload or a selection from a repository of available digital designs. In one or more embodiments, the design reformatting system 106 decomposes the digital design 202 to identify one or more design elements 204. In some embodiments, the design reformatting system 106 defines the one or more design elements 204 according to one or more characteristics. More information regarding the decomposition of the digital design 202 is provided in relation to FIG. 3.

In some cases, a digital design refers to an artistic creation made using digital tools and technologies for use on digital platforms. Specifically, it can refer to a broad range of formats, such as web pages, social media graphics, fliers, mobile app interfaces, or digital advertisements. Further, a digital design is a structured visual or interactive composition optimized for a specific aspect ratio. Relatedly, a design element refers to a component used in creating digital designs. For example, a design element refers to a discrete, segment-able visual component or aspect as part of a larger digital design, such as a digital image or a text box.

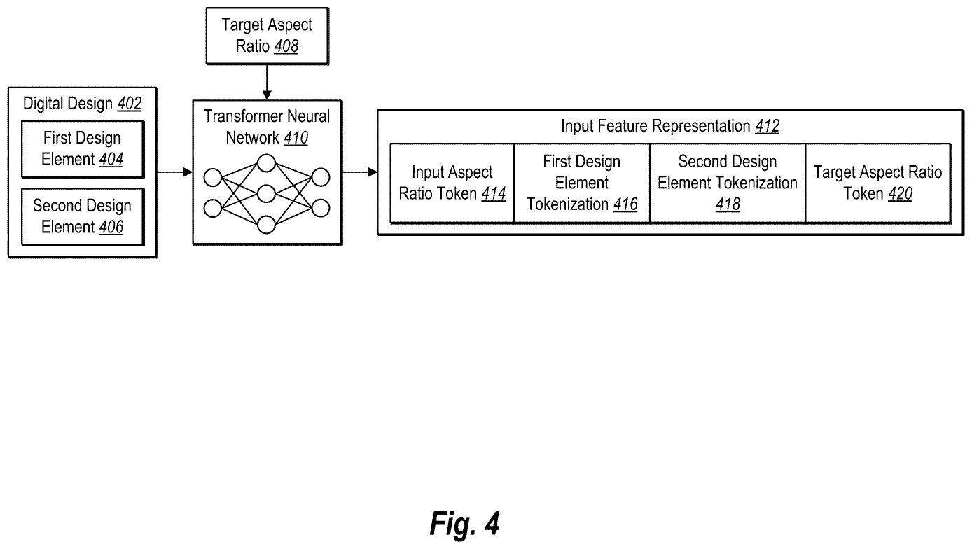

As further illustrated in FIG. 2, the design reformatting system 106 generates an input feature representation 206 from the digital design 202. In particular, the design reformatting system 106 generates the input feature representation 206 by generating a tokenized representation of the digital design 202 and the one or more design elements 204. In one or more embodiments, the design reformatting system 106 generates the input feature representation 206 by generating a tokenization of the aspect ratio of the digital design 202, generating a tokenization for each of the one or more design elements 204, generating a tokenization for a target aspect ratio (e.g., the aspect ratio of the modified digital design 212), and combining the generated tokenizations into the input feature representation 206. Additional detail regarding the generation of the input feature representation 206 is provided in relation to FIG. 4.

In some cases, an input feature representation refers to a structured way of organizing and encoding data for use in machine learning models (e.g., the transformer neural network 208). In some embodiments, an input feature representation is created by encoding input data (e.g., one or more design elements and an input aspect ratio) into one or more tokens. In one or more embodiments, the input feature representation is a combination of the one or more tokens that the machine learning model can process effectively.

In some cases, tokenization in the context of machine learning refers to a process of breaking down input data, such as design elements, into smaller units called tokens. In some embodiments, tokenization includes or refers to encoding individual elements of the input data, such as the characteristic, position, and dimensions of a design element into alternative representations or tokens. This tokenization process creates tokens as input for analyzing and reproducing localized features within a digital design.

In some cases, a token thus includes or refers to a basic unit of data used to represent information. In some embodiments, a token refers to segmented elements derived from input data. For example, a token is a discrete piece of processed data to enable efficient representation and analysis by a machine learning model (e.g., the transformer neural network 208).

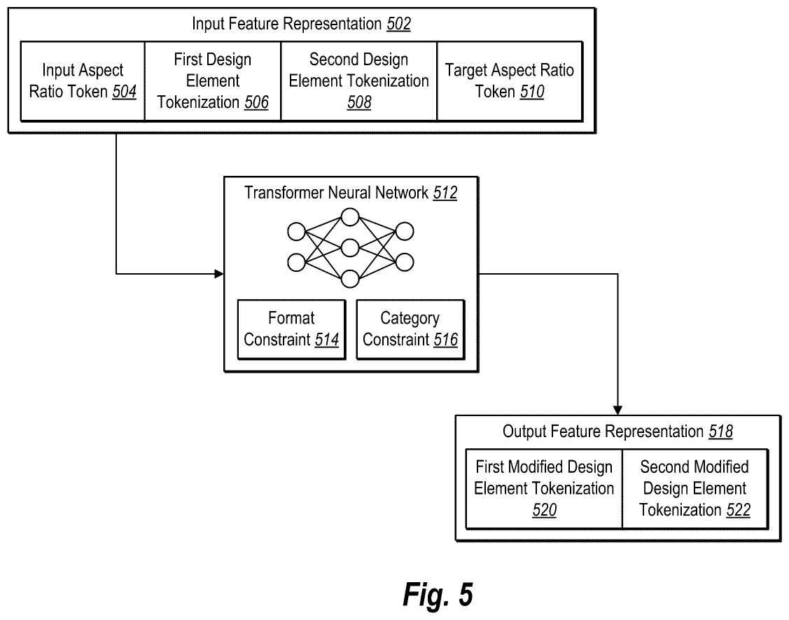

As further illustrated in FIG. 2, the design reformatting system 106 utilizes a transformer neural network 208 to transform the input feature representation 206 into an output feature representation 210. In one or more embodiments, the design reformatting system 106 utilizes the transformer neural network 208 to transform the input feature representation 206 according to one or more constraints (e.g., a format constraint and/or a category constraint). More information regarding utilizing the transformer neural network 208 to transform the input feature representation 206 into the output feature representation 210 is provided in FIG. 5.

In some cases, an output feature representation refers to a transformed feature representation corresponding to a specified target aspect ratio. For example, an output feature representation refers to one or more tokens representing design elements transformed to match a target aspect ratio. In one or more embodiments, an output feature representation is utilized by a machine learning model (e.g., the transformer neural network 208) to generate a modified digital design in a target aspect ratio.

In some cases, a constraint refers to a restriction placed on a machine learning model (e.g., the transformer neural network 208) to guide the machine learning model to generate certain sequence types. In one or more embodiments, a format constraint guides the machine learning model to generate output feature representations that match a specific format. In one or more embodiments, a category constraint guides the machine learning model to generate output feature representations that include design element tokenizations with the same number of tokens as the design element tokenizations in the input feature representations.

As further illustrated in FIG. 2, the design reformatting system 106 generates an output feature representation 210. In particular, the design reformatting system 106 generates the output feature representation 210 by generating modified tokenizations corresponding to the design elements 204 according to the target aspect ratio defined in the input feature representation 206. In one or more embodiments, the design reformatting system 106 generates the output feature representation 210 by redefining the characteristics of the design elements 204 according to the target aspect ratio defined in the input feature representation 206.

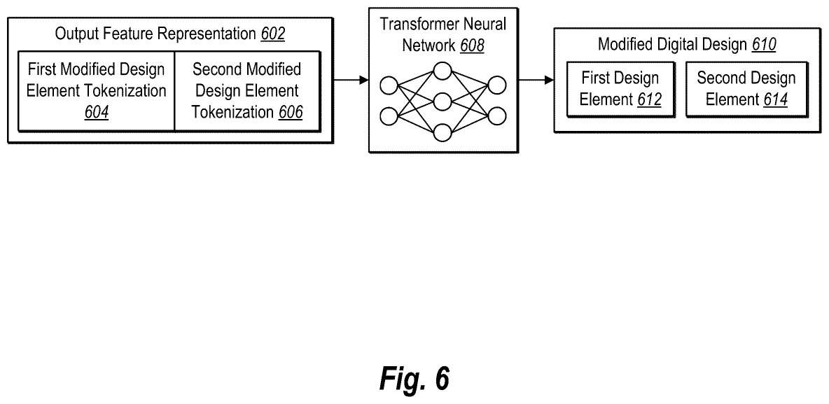

As further illustrated in FIG. 2, the design reformatting system 106 utilizes the output feature representation 210 to generate a modified digital design 212 with one or more design elements 214 corresponding to the one or more design elements 204. In particular, the design reformatting system 106 generates the modified digital design 212 according to the target aspect ratio as defined in the input feature representation 206. In one or more embodiments, the design reformatting system 106 generates the modified digital design 212 in the target aspect ratio defined in the input feature representation 206 while preserving the one or more design elements 214. More information regarding generating the modified digital design 212 is given in relation to FIG. 6.

As mentioned, in one or more embodiments, the design reformatting system 106 decomposes a digital design into one or more design elements. FIG. 3 illustrates a diagram depicting decomposing a digital design into one or more text design elements and one or more image design elements.

As illustrated in FIG. 3, the design reformatting system 106 decomposes a digital design 302 to generate a decomposed digital design 304. In particular, the design reformatting system 106 decomposes the digital design 302 by identifying and defining one or more discrete design elements (e.g., the one or more text design elements 306a-306c and/or the one or more image design element(s) 308) within the digital design 302. In one or more embodiments, as part of generating the decomposed digital design 304, the design reformatting system 106 generates a grid map of the digital design 302. In some embodiments, the design reformatting system 106 decomposes the digital design 302 by prompting a transformer neural network (e.g., the transformer neural network 108) to decompose the digital design 302.

In some cases, decomposition in the context of image processing refers to a process of breaking down an image into simpler components or layers for analysis or manipulation. In particular, decomposition separates an image into meaningful features (e.g., design elements) that are separable, discernable, and/or indiscernible. For example, decomposition can be performed by methods such as wavelet decomposition, Fourier transforms, or principal component analysis to separate an image into features such as frequency components, spatial features, or statistically significant dimensions.

As further illustrated in FIG. 3, the design reformatting system 106 identifies the text design elements 306a-306c and one or more image design element(s) 308 in the decomposed digital design 304. In particular, the design reformatting system 106 defines the text design elements 306a-306c and the one or more image design element(s) 308 by identifying a category characteristic and a set of dimensionality characteristics. In one or more embodiments, the design reformatting system 106 defines the category characteristic of the text design elements 306a-306c and the one or more image design element(s) 308 by defining whether each discrete design element is a text design element or an image design element.

In one or more embodiments, the design reformatting system 106 generates a grid map 310 as part of generating the decomposed digital design 304. In particular, the design reformatting system 106 generates the grid map 310 by overlaying a grid over the decomposed digital design 304 with coordinate positions for each intersection of the grid map 310. In one or more embodiments, the design reformatting system 106 generates the grid map 310 with a grid resolution of 512. In one or more embodiments, the design reformatting system 106 utilizes the grid map 310 to identify a coordinate location characteristic for the text design elements 306a-306c and the image design element(s) 308. In one or more embodiments, the design reformatting system 106 defines the coordinate location characteristic as the top left coordinate of the text design elements 306a-306c and the image design element(s) 308 according to the grid map 310.

In one or more embodiments, the design reformatting system 106 utilizes the grid map 310 to identify a set of dimensionality characteristics of the text design elements 306a-306c and the image design element(s) 308. In one or more embodiments, design reformatting system 106 identifies a width location characteristic of the text design elements 306a-306c and the image design element(s) 308, with the width defined based on the grid map 310. In one or more embodiments, the design reformatting system 106 identifies a height location characteristic of the text design elements 306a-306c and the image design element(s) 308, with the height defined based on the grid map 310. In one or more embodiments the design reformatting system 106 defines the characteristics for the decomposed digital design 304 with the text design elements 306a-306c and for the image design element(s) 308 according to the following format:

$${l}^{′} = [ {c}_{1}^{′} , {x}_{1}^{′} , {y}_{1}^{′} , {w}_{1}^{′} , {h}_{1}^{′} , … , {c}_{N}^{′} , {x}_{N}^{′} , {y}_{N}^{′} , {w}_{N}^{′} , {h}_{N}^{′} ]$$

where l′ is the layout of the digital design 302,

$${c}_{1}^{′}$$

is the category characteristic for a first design element (e.g., one of the text design elements 306a-306c or the image design element(s) 308),

$${x}_{1}^{′}$$

and

$${y}_{1}^{′}$$

are the coordinate locations of the first design element according to the grid map 310, and

$${w}_{1}^{′} and {h}_{1}^{′}$$

are the width location characteristic and the height location characteristic of the first design element according to the grid map 310.

As mentioned, in one or more embodiments, the design reformatting system 106 generates an input feature representation of a digital design. FIG. 4 illustrates a diagram of generating an input feature representation from a digital design in accordance with one or more embodiments.

As illustrated in FIG. 4, the design reformatting system 106 receives a digital design 402 including a first design element 404 and a second design element 406. In particular, the design reformatting system 106 receives the digital design 402 from a client device (e.g., the client device 114). In one or more embodiments, the design reformatting system 106 decomposes the digital design 402 to identify the first design element 404 and the second design element 406.

As further illustrated in FIG. 4, the design reformatting system 106 further receives a target aspect ratio 408. In particular, the design reformatting system 106 receives the target aspect ratio 408 as a selection originating from a client device of a target aspect ratio for a modified digital design. In one or more embodiments, the design reformatting system 106 receives the target aspect ratio 408 which includes one or more target aspect ratios to produce one or more modified digital designs. In one or more embodiments, the design reformatting system 106 receives the target aspect ratio 408 as a client device selection of one or more target aspect ratios from a set of potential target aspect ratios (e.g., 16:9, 4:3, 1:1, 3:4, 9:16, or 21:9). In one or more embodiments, the design reformatting system 106 provides a set of potential target aspect ratios to a client device (e.g., the client device 114), with the set of potential target aspect ratios representing commonly used aspect ratios.

As further illustrated in FIG. 4, the design reformatting system 106 utilizes a transformer neural network 410 to generate an input feature representation 412 from the digital design 402 and the target aspect ratio 408. In particular, the design reformatting system 106 utilizes the transformer neural network 410 to decompose the digital design 402 to identify discrete design elements (e.g., the first design element 404 and the second design element 406). In one or more embodiments, the design reformatting system 106 utilizes the transformer neural network 410 to generate the input feature representation 412 by combining the features of the digital design 402 with the target aspect ratio 408.

As further illustrated in FIG. 4, the design reformatting system 106 generates the input feature representation 412 to represent the features of the digital design 402 and the target aspect ratio 408. In particular, the design reformatting system 106 generates the input feature representation 412 to include an input aspect ratio token 414, a first design element tokenization 416, a second design element tokenization 418, and a target aspect ratio token 420. In one or more embodiments, the design reformatting system 106 generates the input feature representation 412 by combining the input aspect ratio token 414, the first design element tokenization 416, the second design element tokenization 418, and the target aspect ratio token 420. In one or more embodiments, the design reformatting system 106 generates the input feature representation 412 by concatenating the input aspect ratio token 414, the first design element tokenization 416, the second design element tokenization 418, and the target aspect ratio token 420. In one or more embodiments, the design reformatting system 106 formats the input feature representation 412 according to the following sequence:

$$〈 SOS 〉 AR \vert {C}_{1} \vert {X}_{1} \vert {Y}_{1} \vert {W}_{1} \vert {H}_{1} \vert … \vert {C}_{N} \vert {X}_{N} \vert {Y}_{N} \vert {W}_{N} \vert {H}_{N} \vert 〈 SEP 〉 \vert {AR}^{′}$$

where [symbol] SOS [symbol] denotes the start of the sequence, AR denotes the initial aspect ratio (e.g., the input aspect ratio token 414), C₁ represents the category of the first design element tokenization 416 (e.g., whether the first design element 404 is a text design element or an image design element), X₁ and Y₁ represent the center coordinate of the first design element 404, W₁ and H₁ represent the width and height of the first design element 404, [symbol] SEP [symbol] denotes a separator token to indicate the transition between the input layout and the target layout, and AR′ indicates the target aspect ratio token 420.

As further illustrated in FIG. 4, the design reformatting system 106 generates an input aspect ratio token 414 as part of the input feature representation 412. In particular, the design reformatting system 106 generates the input aspect ratio token 414 as a representation of the aspect ratio of the digital design 402. In one or more embodiments, the design reformatting system 106 generates the input aspect ratio token 414 by prompting the transformer neural network 410 to decompose the digital design 402 and tokenize the aspect ratio identified for the digital design 402.

As further illustrated in FIG. 4, the design reformatting system 106 generates a first design element tokenization 416 and a second design element tokenization 418 as part of the input feature representation 412. In particular, the design reformatting system 106 generates the first design element tokenization 416 as a representation of the characteristics of the first design element 404 and the second design element tokenization 418 as a representation of the characteristics of the second design element 406. In one or more embodiments, the design reformatting system 106 generates the first design element tokenization 416 and the second design element tokenization 418 as a representation encoding: (i) a category characteristic of the discrete design elements (e.g., is the discrete design element a text design element or an image design element), and (ii) a set of dimensionality characteristics including a coordinate location characteristic of the discrete design elements (e.g., the center coordinate of the discrete design element as a coordinate location in a grid map) and a height location characteristic and a width location characteristic of the discrete design elements (e.g., the height and width of the discrete design element). In one or more embodiments, the design reformatting system 106 encodes the first design element tokenization 416 and the second design element tokenization 418 as 5-tuples representing the category characteristic and the set of dimensionality characteristics.

As further illustrated in FIG. 4, the design reformatting system 106 generates the target aspect ratio token 420 as part of the input feature representation 412. In particular, the design reformatting system 106 generates the target aspect ratio token 420 to represent the target aspect ratio 408. In one or more embodiments, the design reformatting system 106 inserts a separator token between the target aspect ratio token 420 and the rest of the input feature representation 412 to indicate that the target aspect ratio token 420 corresponds to a target aspect ratio instead of the aspect ratio of the digital design 402.

As mentioned, in one or more embodiments, the design reformatting system 106 transforms an input feature representation into an output feature representation. FIG. 5 illustrates a diagram of utilizing a transformer neural network to transform the input feature representation into an output feature representation according to one or more constraints in accordance with one or more embodiments.

As illustrated in FIG. 5, the design reformatting system 106 generates an input feature representation 502 including an input aspect ratio token 504, a first design element tokenization 506, a second design element tokenization 508, and a target aspect ratio token 510. In one or more embodiments, the design reformatting system 106 generates the input feature representation 502 according to the process depicted in FIG. 4.

As further illustrated in FIG. 5, the design reformatting system 106 utilizes a transformer neural network 512 to transform the input feature representation 502 into an output feature representation 518. In particular, the design reformatting system 106 utilizes the transformer neural network 512 to process the input feature representation 502 as a conditional input, iteratively generating the output feature representation 518 based on the context of the input feature representation 502. In one or more embodiments, the transformer neural network 512 utilizes a decoder-only transformer architecture (e.g., a decoder-only large language model configuration).

As further illustrated in FIG. 5, the design reformatting system 106 utilizes the transformer neural network 512 according to a format constraint 514. In particular, the design reformatting system 106 enforces the format constraint 514 on the transformer neural network 512 to ensure that the transformer neural network 512 generates the output feature representation 518 in a specific format. In one or more embodiments, the design reformatting system 106 leverages the format constraint 514 to ensure that the output feature representation 518 includes concatenated 5-tuples representing the design elements (e.g., the first modified design element tokenization 520 and the second modified design element tokenization 522) appended with an end-of-sequence token. In one or more embodiments, the design reformatting system 106 utilizes the format constraint 514 to mask one or more noncompliant token sequences from the output feature representation 518.

As further illustrated in FIG. 5, the design reformatting system 106 utilizes the transformer neural network 512 according to a category constraint 516. In particular, the design reformatting system 106 enforces the category constraint 516 on the transformer neural network 512 to ensure that the transformer neural network 512 generates the output feature representation 518 by comparing the number of design element attributes in each modified design element tokenization (e.g., the first modified design element tokenization 520 and the second modified design element tokenization 522) in the output feature representation 518 with the number of design element attributes in each design element tokenization (e.g., the first design element tokenization 506 and the second design element tokenization 508) in the input feature representation 502. In one or more embodiments, the design reformatting system 106 leverages the category constraint 516 to ensure that the modified design element tokenizations are 5-tuples including a category characteristic and a set of dimensionality characteristics.

As further illustrated in FIG. 5, the design reformatting system 106 utilizes the transformer neural network 512 to generate the output feature representation 518 according to the format constraint 514 and the category constraint 516. In particular, the design reformatting system 106 utilizes the transformer neural network 512 to generate the output feature representation 518 by utilizing the format constraint 514 and the category constraint 516 to remove sequences that do not satisfy the format constraint 514 and/or the category constraint 516. In one or more embodiments, the design reformatting system 106 utilizes the transformer neural network 512 to iteratively predict valid tokens while masking out tokens that do not conform to the format constraint 514 and/or the category constraint 516 to ensure that the output feature representation 518 maintains the structural integrity and category consistency of the input feature representation 502. In one or more embodiments, the design reformatting system 106 generates the output feature representation 518 according to the following format:

$$\vert {C}_{1}^{′} \vert \vert {X}_{1}^{′} \vert \vert {Y}_{1}^{′} \vert \vert {W}_{1}^{′} \vert \vert {H}_{1}^{′} \vert … \vert {C}_{N}^{′} \vert \vert {X}_{N}^{′} \vert \vert {Y}_{N}^{′} \vert \vert {W}_{N}^{′} \vert \vert {H}_{N}^{′} \vert 〈 EOS 〉$$

where

$${C}_{1}^{′}$$

represents the category of the first design element in the target aspect ratio,

$${X}_{1}^{′} and {Y}_{1}^{l}$$

represent the center coordinate of the first design element in the target aspect ratio,

$${W}_{1}^{′} and {H}_{1}^{′}$$

represent the width and height of the first design element in the target aspect ratio, and [symbol] EOS [symbol] indicates the end of sequence.

In one or more embodiments, the design reformatting system 106 generates the output feature representation 518 according to the following algorithm:

| | |
|---|---|
| 1: | procedure ADDBOXTOKENS(tokens, BoxesListᵢₙ) |
| 2: | for each boxᵢ in BoxesListᵢₙ do |
| 3: | Cᵢ←Category of boxᵢ |
| 4: | Xᵢ←X-coordinate of boxᵢ |
| 5: | Yᵢ←Y-coordinate of boxᵢ |
| 6: | Wᵢ←Width of boxᵢ |
| 7: | Hᵢ←Height of boxᵢ |
| 8: | Add (Cᵢ, Xᵢ, Yᵢ, Wᵢ, Hᵢ) to tokens |
| 9: | |
| 10: | Procedure GETINPUTTOKENS (ARᵢₙ, BoxesListᵢₙ, ARₒᵤₜ) |
| 11: | Initialize an empty list tokens |
| 12: | Add [symbol] SOS [symbol] and ARᵢₙ to tokens |
| 13: | Add all box tokens to tokens by calling ADDBOXTOKENS (tokens, BoxesListᵢₙ) |
| 14: | Add [symbol] SEP [symbol] and ARₒᵤₜ to tokens |
| 15: | return tokens |
| 16: | |
| 17: | procedure PREDICTNEXTTOKEN (tokens, C_{current(} |
| 18: | Append token for C_{current} to tokens |
| 19: | for i = 0 to 3 do |
| 20: | nextTokenLogits←PredictNextToken(tokens) |
| 21: | Mask out logits for [symbol] SOS [symbol] , [symbol] SEP [symbol] , and [symbol] EOS [symbol] by setting their probability to - ∞ |
| 22: | nextToken←sample_from_softmax (nextTokenLogits) |
| 23: | Append nextToken to tokens |
| 24: | return tokens |
| 25: | |
| 26: | procedure CONSTRAINEDINFERENCE(ARᵢₙ, BoxesListᵢₙ, ARₒᵤₜ) |
| 27: | Initialize an empty list tokens |
| 28: | tokens←GETINPUTTOKENS(AR_{in,} BoxesListᵢₙ, ARₒᵤₜ) |
| 29: | Initialize remaining_boxes←BoxesListᵢₙ |
| 30: | while remaining_boxes is not empty do |
| 31: | box_{current}←Pop first box from remaining_boxes |
| 32: | C_{current}←Category of box_{current} |
| 33: | tokens←PredictNextToken(tokens, C_{current}) |
| 34: | Add [symbol] SEP [symbol] and ARₒᵤₜ to tokens |
| 35: | return tokens |

As further illustrated in FIG. 5, the design reformatting system 106 generates the output feature representation 518 including a first modified design element tokenization 520 and a second modified design element tokenization 522. In particular, the design reformatting system 106 generates the first modified design element tokenization 520 and the second modified design element tokenization 522 to represent the first design element tokenization 506 and the second design element tokenization 508 as updated to match the target aspect ratio as represented by the target aspect ratio token 510. In one or more embodiments, the design reformatting system 106 generates the first modified design element tokenization 520 and the second modified design element tokenization 522 as 5-tuples encoding one or more characteristics of a discrete design element (e.g., the category characteristic, the set of dimensionality characteristics) according to the target aspect ratio.

As mentioned, in one or more embodiments, the design reformatting system 106 utilizes an output feature representation to generate a modified digital design. FIG. 6 illustrates a diagram of utilizing a transformer neural network to generate a modified digital design from an output feature representation.

As illustrated in FIG. 6, the design reformatting system 106 generates an output feature representation 602 including a first modified design element tokenization 604 and a second modified design element tokenization 606. The design reformatting system 106 generates the output feature representation 602 to represent a digital image with one or more design elements (e.g., as the first modified design element tokenization 604 and the second modified design element tokenization 606) according to a target aspect ratio. In one or more embodiments, the design reformatting system 106 generates the output feature representation 602 to encode a target aspect ratio.

As further illustrated in FIG. 6, the design reformatting system 106 utilizes a transformer neural network 608 to generate a modified digital design 610 from the output feature representation 602. In particular, the design reformatting system 106 utilizes the transformer neural network 608 to generate the modified digital design 610 in the target aspect ratio, as specified by the output feature representation 602. In one or more embodiments, the design reformatting system 106 utilizes the transformer neural network 608 to generate the modified digital design 610 from the output feature representation 602, with the modified digital design 610 including a first design element 612 and a second design element 614, placing the first design element 612 in the modified digital design 610 based off the first modified design element tokenization 604 and placing the second design element 614 in the modified digital design 610 based off the second modified design element tokenization 606. In one or more embodiments, the design reformatting system 106 utilizes the transformer neural network 608 to generate the modified digital design 610 in the target aspect ratio, while preserving the design integrity of the first design element 612 and the second design element 614 from an initial digital design (e.g., the digital design 402 with the first design element 404 and the second design element 406). In one or more embodiments, the design reformatting system 106 generates the modified digital design 610 for display on a client device (e.g., the client device 114).

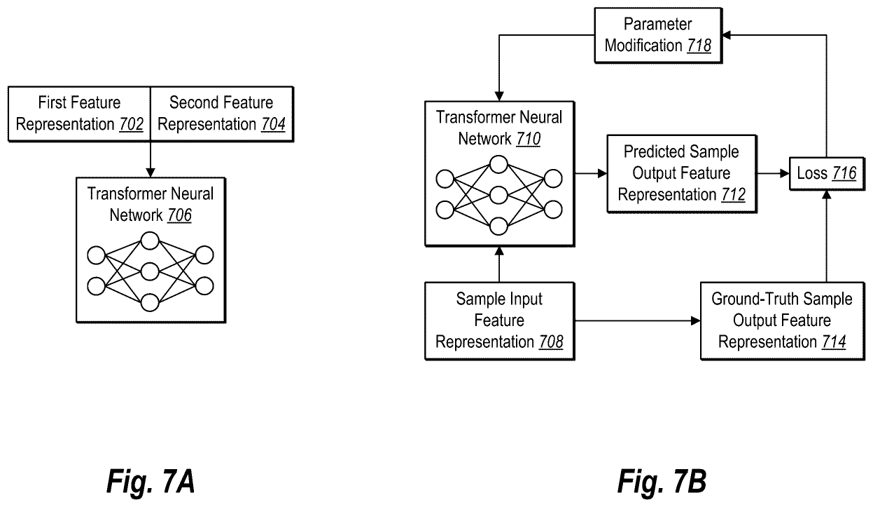

As mentioned, in one or more embodiments, the design reformatting system 106 trains a transformer neural network to generate modified digital designs. FIGS. 7A-7B illustrate diagrams of training a transformer neural network in accordance with one or more embodiments. FIG. 7A illustrates a diagram of utilizing a pretraining process to pretrain the transformer neural network to recognize the patterns of the feature representations in accordance with one or more embodiments. FIG. 7B illustrates a diagram of finetuning the transformer neural network to generate predicted output feature representations in accordance with one or more embodiments.

As illustrated in FIG. 7A, the design reformatting system 106 selects a first feature representation 702 and a second feature representation 704 as input for a transformer neural network 706. In particular, the design reformatting system 106 selects the first feature representation 702 and the second feature representation 704 by sampling two random feature representation sequences from a dataset stored locally (e.g., on the server device(s) 102) or remotely (e.g., on the database 112 or the client device 114). In one or more embodiments, the design reformatting system 106 combines the first feature representation 702 and the second feature representation 704 to use as input for the transformer neural network 706. In one or more embodiments, the design reformatting system 106 combines the first feature representation 702 and the second feature representation 704 by concatenating the first feature representation 702 and the second feature representation 704.

As further illustrated in FIG. 7A, the design reformatting system 106 utilizes the first feature representation 702 and the second feature representation 704 to pretrain the transformer neural network 706. In particular, the design reformatting system 106 pretrains the transformer neural network 706 to recognize underlying structural and semantic patterns of the layouts of the first feature representation 702 and the second feature representation 704. In one or more embodiments, the design reformatting system 106 pretrains the transformer neural network 706 on the first feature representation 702 and the second feature representation 704 to ensure that the transformer neural network 706 understands the spatial relationships and visual consistency between design elements as represented in feature representations (e.g., the first feature representation 702 and the second feature representation 704).

As illustrated in FIG. 7B, the design reformatting system 106 accesses a sample input feature representation 708 and a ground-truth sample output feature representation 714. In one or more embodiments, the design reformatting system 106 accesses the sample input feature representation 708 and the ground-truth sample output feature representation 714 from a dataset stored locally (e.g., on the server device(s)) or remotely (e.g., on the database or the client device). In one or more embodiments, the design reformatting system 106 accesses the sample input feature representation 708 and the ground-truth sample output feature representation 714 as a pair, with the sample input feature representation 708 correlating with the ground-truth sample output feature representation 714.

As further illustrated in FIG. 7B, the design reformatting system 106 utilizes a transformer neural network 710 to generate a predicted sample output feature representation 712 from the sample input feature representation 708. In one or more embodiments, the design reformatting system 106 utilizes the transformer neural network to generate the predicted sample output feature representation 712 to represent the same digital design and design elements as depicted in the sample input feature representation 708 in a different aspect ratio.

As further illustrated in FIG. 7B, the design reformatting system 106 compares the predicted sample output feature representation 712 with the ground-truth sample output feature representation 714 to generate a loss 716. In particular, the design reformatting system 106 generates the loss 716 to determine the difference between the predicted sample output feature representation 712 and the ground-truth sample output feature representation 714. In one or more embodiments, the design reformatting system 106 uses a loss function (e.g., mean squared error, mean absolute error, or Huber loss) to calculate the difference between the predicted sample output feature representation 712 and the ground-truth sample output feature representation 714.

As further illustrated in FIG. 7B, the design reformatting system 106, based on the loss 716, performs a parameter modification 718 to finetune the transformer neural network 710. In particular, the design reformatting system 106 uses the parameter modification 718 to finetune the parameters of the transformer neural network 710 to improve the ability of the transformer neural network 710 to generate the predicted sample output feature representation 712 as matching the ground-truth sample output feature representation 714. In one or more embodiments, the design reformatting system 106 uses the following optimization algorithm as part of the parameter modification 718:

$$L = - {\sum }_{t = 1}^{\vert L \vert} {\sum }_{v ∈ V} {y}_{t , v} log {\hat{y}}_{t , v}$$

where L is the loss value, |L| is the length of the layout sequence, V is the vocabulary of possible tokens, y_{t,v} is a one-hot encoded target token at position t with v being the index of the target token, and ŷ_{t,v} is the predicted probability for the token v at position t.

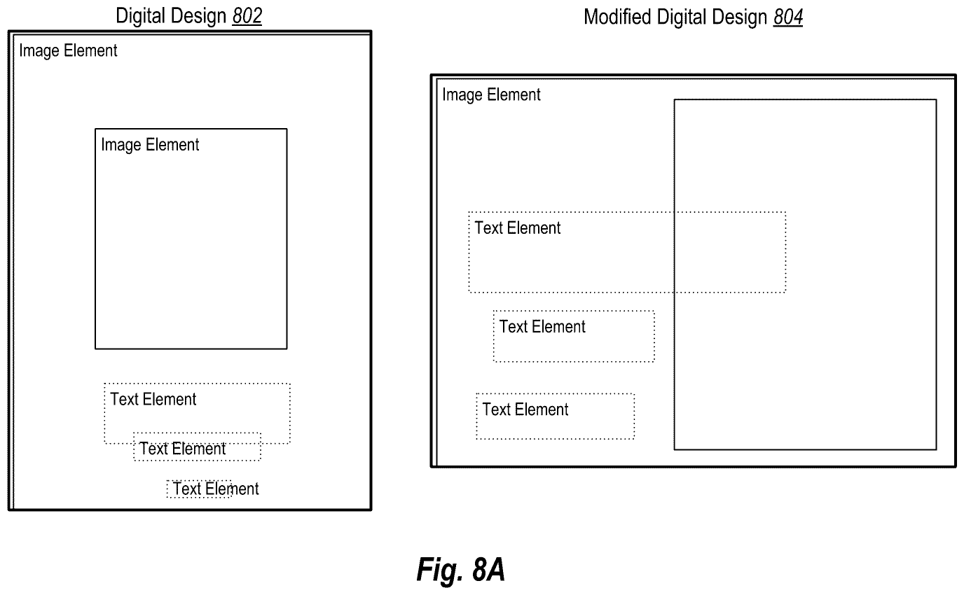

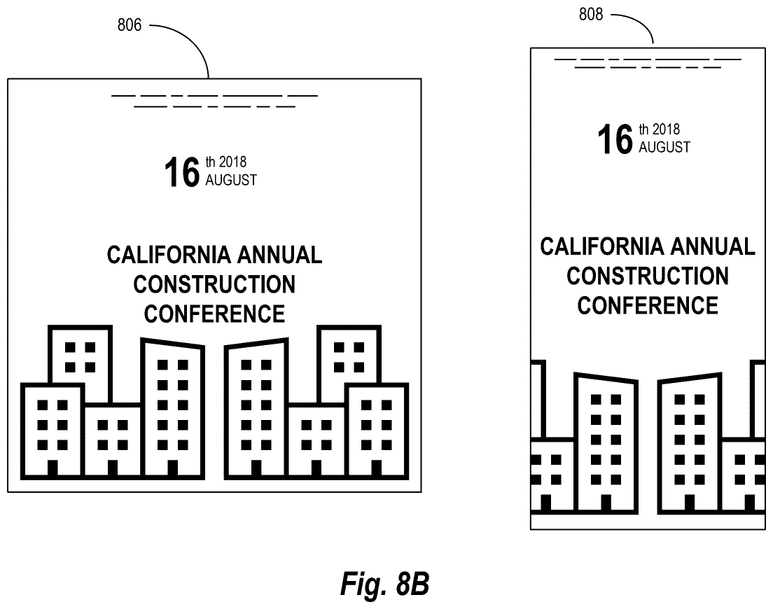

As mentioned, in one or more embodiments, the design reformatting system 106 generates modified digital designs that maintain the integrity of the discrete design elements of an original digital design in a different aspect ratio. FIGS. 8A-8B illustrate example images of transforming a digital design into a modified digital design in accordance with one or more embodiments. FIG. 8A illustrates generating a modified digital design with labeled discrete design elements in accordance with one or more embodiments. FIG. 8B illustrates generating a modified digital design in accordance with one or more embodiments.

As illustrated in FIG. 8A, the design reformatting system 106 generates a modified digital design 804 from a digital design 802. As depicted, the design reformatting system 106 generates the modified digital design 804 in a different aspect ratio and layout than the digital design 802 while preserving the category of and the relative location of the discrete design elements included in the digital design 802.

As illustrated in FIG. 8B, the design reformatting system 106 generates a modified digital design 808 from a digital design 806. As depicted, the design reformatting system 106 generates the modified digital design 808 in a different aspect ratio than the digital design 806 while preserving the relative location of the discrete design elements included in the digital design 802. Further, as depicted, the design reformatting system 106 generates the modified digital design 808 while preserving the text and images present in the digital design 806.

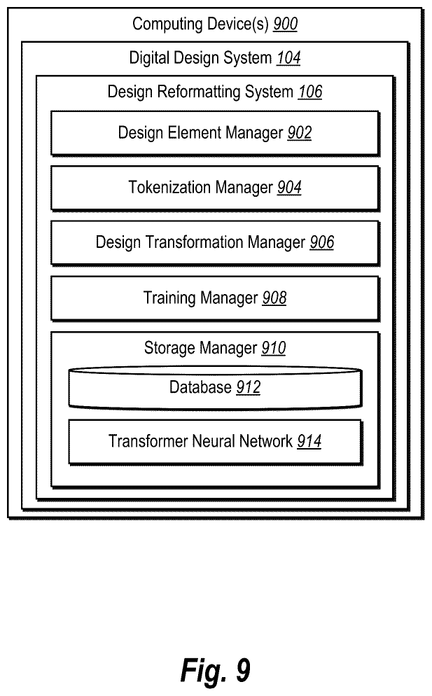

Referring now to FIG. 9, additional detail will be provided regarding components and capabilities of the design reformatting system 106. Specifically, FIG. 9 illustrates an example schematic diagram of the design reformatting system 106 on an example computing device(s) 900 (e.g., one or more of the client device 114 and/or the server device(s) 102). As shown in FIG. 9, the design reformatting system 106 includes a design element manager 902, a tokenization manager 904, a design transformation manager 906, a training manager 908, and a storage manager 910.

As mentioned, the design reformatting system 106 includes a design element manager 902. In particular, the design element manager 902 identifies, modifies, alters, or selects one or more design elements (e.g., the text design elements 306a-306c and the image design element(s) 308). For example, the design element manager 902 decomposes a digital design to identify and define one or more characteristics of one or more design elements present in a digital design.

As mentioned, the design reformatting system 106 includes a tokenization manager 904. In particular, the tokenization manager 904 generates, modifies, or alters one or more tokenizations encoding an initial aspect ratio, a target aspect ratio, and one or more design elements of a digital design. For example, the tokenization manager 904 generates one or more tokenizations (e.g., the first design element tokenization 416 or the second design element tokenization 418) to represent features of one or more design elements (e.g., a category characteristic defining whether a design element is an image design element or a text design element or a set of dimensionality characteristics defining the location and dimensions of a design element).

As mentioned, the design reformatting system 106 includes a design transformation manager 906. In particular, the design transformation manager 906 generates, modifies, or alters a modified digital design from a digital design. For example, the design transformation manager 906 generates a modified digital design (e.g., the modified digital design 610) from tokenizations depicting the design elements of the digital design (e.g., the first modified design element tokenization 604 and the second modified design element tokenization 606).

As mentioned, the design reformatting system 106 includes a training manager 908. In particular, the training manager 908 trains a transformer neural network (e.g., the transformer neural network 914) to generate modified digital images. For example, the training manager 908 accesses a training dataset and trains the transformer neural network to predict output feature representations by performing a pretraining process and a finetuning process, as describe herein.

The design reformatting system 106 further includes a storage manager 910. The storage manager 910 operates in conjunction with the other components of the design reformatting system 106 and includes one or more memory devices such as the database 912 (e.g., the database 112) that stores various data such as digital designs and other information. In some cases, the storage manager 910 also manages or maintains a transformer neural network 914 for generating modified digital designs using one or more components of the design reformatting system 106 as described above.

In one or more embodiments, each of the components of the design reformatting system 106 are in communication with one another using any suitable communication technologies. Additionally, the components of the design reformatting system 106 are in communication with one or more other devices including one or more client devices described above. It will be recognized that although the components of the design reformatting system 106 are shown to be separate in FIG. 9, any of the subcomponents may be combined into fewer components, such as into a single component, or divided into more components as may serve a particular implementation. Furthermore, although the components of FIG. 9 are described in connection with the design reformatting system 106, at least some of the components for performing operations in conjunction with the design reformatting system 106 described herein may be implemented on other devices within the environment.

The components of the design reformatting system 106 include software, hardware, or both. For example, the components of the design reformatting system 106 include one or more instructions stored on a computer-readable storage medium and executable by processors of one or more computing devices (e.g., the computing device(s) 900). When executed by the one or more processors, the computer-executable instructions of the design reformatting system 106 cause the computing device(s) 900 to perform the methods described herein. Alternatively, the components of the design reformatting system 106 comprise hardware, such as a special purpose processing device to perform a certain function or group of functions. Additionally, or alternatively, the components of the design reformatting system 106 include a combination of computer-executable instructions and hardware.

Furthermore, the components of the design reformatting system 106 performing the functions described herein may, for example, be implemented as part of a stand-alone application, as a module of an application, as a plug-in for applications including content management applications, as a library function or functions that may be called by other applications, and/or as a cloud-computing model. Thus, the components of the design reformatting system 106 may be implemented as part of a stand-alone application on a personal computing device or a mobile device. Alternatively, or additionally, the components of the design reformatting system 106 may be implemented in any application that allows creation and delivery of content to users, including, but not limited to, ADOBE® applications such as ACROBAT®, ACROBAT STANDARD, PHOTOSHOP®, ILLUSTRATOR®, and ACROBAT MOBILE. “ADOBE,” “ACROBAT,” “PHOTOSHOP,” and “ILLUSTRATOR,” are either registered trademarks or trademarks of Adobe Inc. in the United States and/or other countries.

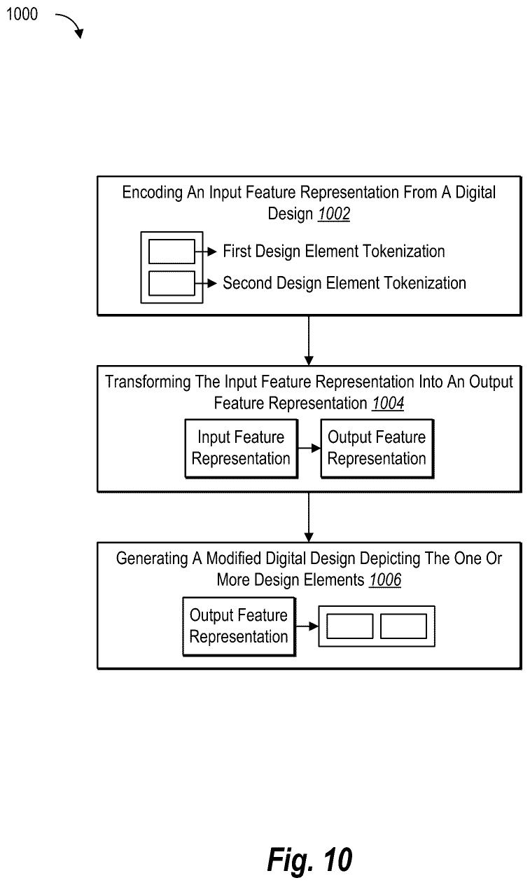

FIGS. 1-9, the corresponding text, and the examples provide a number of different systems, methods, and non-transitory computer readable media for generating a modified digital design by generating a feature design representation of the digital design and generating a modified digital design based on a modified feature design representation. In addition to the foregoing, embodiments can also be described in terms of flowcharts comprising acts for accomplishing a particular result. For example, FIG. 10 illustrates a flowchart of example sequences or series of acts in accordance with one or more embodiments.

While FIG. 10 illustrates acts according to particular embodiments, alternative embodiments may omit, add to, reorder, and/or modify any of the acts shown in FIG. 10. The acts of FIG. 10 can be performed as part of a method. Alternatively, a non-transitory computer readable medium can comprise instructions that, when executed by one or more processors, cause a computing device to perform the acts of FIG. 10. In still further embodiments, a system can perform the acts of FIG. 10. Additionally, the acts described herein may be repeated or performed in parallel with different instances of the same or other similar acts.

FIG. 10 illustrates an example series of acts 1000 for generating a modified digital design. In particular, the series of acts 1000 includes an act 1002 of encoding a feature representation from a digital design. For example, the act 1002 involves encoding an input feature representation including design element tokenizations of the design elements within the digital design. Further, the series of acts 1000 includes an act 1004 of transforming the input feature representation into an output feature representation. For example, the act 1004 involves utilizing a transformer neural network to transform the input feature representation into the output feature representation by generating modified tokenization of the one or more design elements. Further, the series of acts 1000 includes an act 1006 of generating a modified digital design depicting the one or more design elements. For example, the act 1006 involves generating the modified digital design depicting the one or more design elements according to the target aspect ratio.

In some embodiments, the series of acts 1000 includes identifying, utilizing the transformer neural network, the one or more design elements depicted in the digital design. The series of acts 1000 also includes tokenizing the one or more design elements by generating one or more layout representation tokens corresponding to the one or more design elements. The series of acts 1000 also includes combining the one or more layout representation tokens with the first aspect ratio token and the second aspect ratio token.

In some embodiments, the series of acts 1000 includes defining a data structure representing a set of characteristics of the one or more design elements. The series of acts 1000 also includes generating a 5-tuple defining: a category characteristic of a design element of the one or more design elements; a coordinate location characteristic of the design element; and a set of dimensionality characteristics of the design element.

In some embodiments, the series of acts 1000 includes concatenating the one or more layout representation tokens with the first aspect ratio token and the second aspect ratio token to form the input feature representation. The series of acts 1000 also includes modifying the tokenization of the one or more design elements from encoding characteristics of the one or more design elements according to the initial aspect ratio to encoding the characteristics of the one or more design elements according to the target aspect ratio. The series of acts 1000 also includes populating the modified digital design with the one or more design elements corresponding to a layout of the digital design according to the target aspect ratio.

In some embodiments, the series of acts 1000 includes decomposing a digital design formatted according to an initial aspect ratio into one or more discrete design elements comprising visual components within the digital design; encoding, using a transformer neural network, the one or more discrete design elements into respective tokenizations; generating an input feature representation of the digital design by combining the respective tokenizations with an initial aspect ratio token representing the initial aspect ratio and a target aspect ratio token representing a target aspect ratio for the digital design; and generating, from the input feature representation utilizing the transformer neural network, a modified digital design depicting the one or more discrete design elements according to the target aspect ratio.

In some embodiments, the series of acts 1000 includes identifying, utilizing the transformer neural network, the one or more discrete design elements within the digital design; defining a category characteristic corresponding to a design element among the one or more discrete design elements; and defining a set of dimensionality characteristics for the design element. The series of acts 1000 also includes labeling the design element as an image design element or a text design element.

In some embodiments, the series of acts 1000 includes generating a grid map for the digital design; identifying, utilizing the grid map of the digital design, a coordinate location characteristic defining a center coordinate of the design element; identifying, utilizing the grid map of the digital design, a width location characteristic defining a width value of the design element; and identifying, utilizing the grid map of the digital design, a height location characteristic defining a height value of the design element.

In some embodiments, the series of acts 1000 includes receiving the digital design and a client device selection specifying the target aspect ratio for the digital design from a client device. The series of acts 1000 also includes providing the modified digital design for display within a graphical user interface on a client device.

In some embodiments, the series of acts 1000 includes encoding, utilizing a transformer neural network, an input feature representation from a digital design depicting one or more design elements by generating attribute tokens from design element attributes of the one or more design elements; determining a format constraint defining a layout sequence of tokens for an output feature representation corresponding to the input feature representation; determining, for the output feature representation, a category constraint defining a number of design element attributes corresponding to respective category tokens within the input feature representation; and transforming, utilizing the transformer neural network, the input feature representation into the output feature representation by modifying and arranging the attribute tokens of the input feature representation according to the format constraint and the category constraint.

In some embodiments, the series of acts 1000 includes training the transformer neural network by: performing a pretraining process by providing, to the transformer neural network, a first feature representation as input and a second feature representation as output; and performing a fine-tuning process by providing, to the transformer neural network, a sample input feature representation as input and a sample output feature representation as output. The series of acts 1000 also includes providing, to the transformer neural network, a concatenated feature representation comprising the first feature representation and the second feature representation. The series of acts 1000 also includes training the transformer neural network to transform the sample input feature representation to an aspect ratio of the sample output feature representation.

In some embodiments, the series of acts 1000 includes predicting, utilizing the transformer neural network, the layout sequence of tokens for the output feature representation; and masking one or more noncompliant token sequences from the layout sequence of tokens.

In some embodiments, the series of acts 1000 includes identifying, utilizing the transformer neural network, a category characteristic for the one or more design elements; encoding the respective category tokens for the category characteristic in the input feature representation; and determining whether the output feature representation includes the number of design element attributes within the input feature representation by comparing a number of category tokens in the output feature representation to a number of category tokens in the input feature representation.

In some embodiments, the series of acts 1000 includes training the transformer neural network by: generating a sample output feature representation based on a sample input feature representation; comparing the sample output feature representation to a ground truth output feature representation to determine a loss value; and modifying parameters of the transformer neural network based on the loss value.

Embodiments of the present disclosure may comprise or utilize a special purpose or general-purpose computer including computer hardware, such as, for example, one or more processors and system memory, as discussed in greater detail below. Embodiments within the scope of the present disclosure also include physical and other computer-readable media for carrying or storing computer-executable instructions and/or data structures. In particular, one or more of the processes described herein may be implemented at least in part as instructions embodied in a non-transitory computer-readable medium and executable by one or more computing devices (e.g., any of the media content access devices described herein). In general, a processor (e.g., a microprocessor) receives instructions, from a non-transitory computer-readable medium, (e.g., a memory, etc.), and executes those instructions, thereby performing one or more processes, including one or more of the processes described herein.

Computer-readable media can be any available media that can be accessed by a general purpose or special purpose computer system. Computer-readable media that store computer-executable instructions are non-transitory computer-readable storage media (devices). Computer-readable media that carry computer-executable instructions are transmission media. Thus, by way of example, and not limitation, embodiments of the disclosure can comprise at least two distinctly different kinds of computer-readable media: non-transitory computer-readable storage media (devices) and transmission media. Non-transitory computer-readable storage media (devices) includes optical and/or non-optical memory, disks, or caches that store computer data interpretable by one or more processors to execute particular functions as described herein. A “network” is defined as one or more data links that enable the transport of electronic data between computer systems and/or modules and/or other electronic devices. Information is transferred or provided over a network (either hardwired, wireless, or a combination of hardwired or wireless) to a computer to carry program code in the form of computer-executable instructions or data structures and which can be accessed by a general purpose or special purpose computer.

Computer-executable instructions comprise, for example, instructions and data which, when executed at a processor, cause a general-purpose computer, special purpose computer, or special purpose processing device to perform a certain function or group of functions. In some embodiments, computer-executable instructions are executed on a general-purpose computer to turn the general-purpose computer into a special purpose computer implementing elements of the disclosure. The computer executable instructions may be, for example, binaries, intermediate format instructions such as assembly language, or even source code.

Embodiments of the present disclosure can also be implemented in cloud computing environments. In this description, “cloud computing” is defined as a model for enabling on-demand network access to a shared pool of configurable computing resources. A cloud-computing model can also expose various service models, such as, for example, Software as a Service (“SaaS”), Platform as a Service (“PaaS”), and Infrastructure as a Service (“IaaS”). A cloud-computing model can also be deployed using different deployment models such as private cloud, community cloud, public cloud, hybrid cloud, and so forth.

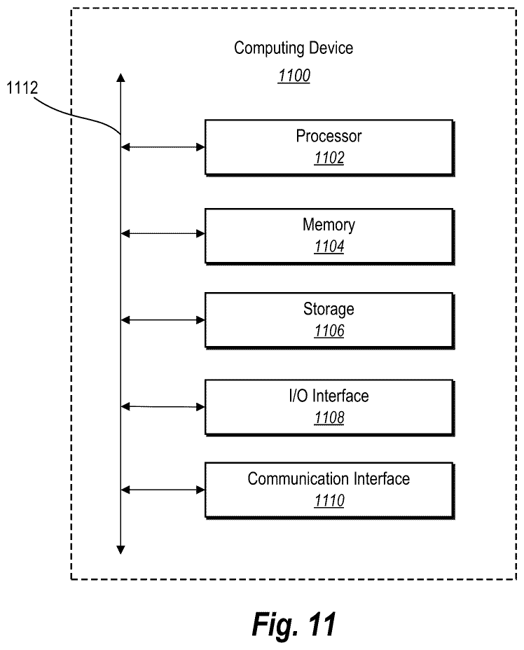

FIG. 11 illustrates, in block diagram form, an example computing device 1100 (e.g., the computing device(s) 900, the client device 114, and/or the server device(s) 102) that may be configured to perform one or more of the processes described above. As shown by FIG. 11, the computing device can comprise a processor(s) 1102, memory 1104, a storage device 1106, an I/O interface 1108, and a communication interface 1110.

In particular embodiments, processor(s) 1102 includes hardware for executing instructions, such as those making up a computer program. As an example, and not by way of limitation, to execute instructions, processor(s) 1102 may retrieve (or fetch) the instructions from an internal register, an internal cache, memory 1104, or a storage device 1106 and decode and execute them. The computing device 1100 includes memory 1104, which is coupled to the processor(s) 1102. The memory 1104 may be used for storing data, metadata, and programs for execution by the processor(s). The memory 1104 may include one or more of volatile and non-volatile memories. The memory 1104 may be internal or distributed memory. The computing device 1100 includes a storage device 1106 includes storage for storing data or instructions. As an example, and not by way of limitation, storage device 1106 can comprise a non-transitory storage medium described above. The computing device 1100 also includes one or more input or output (“I/O”) devices/interfaces 1108, which are provided to allow a user to provide input to (such as user strokes), receive output from, and otherwise transfer data to and from the computing device 1100. These I/O devices/interfaces 1108 may include a mouse, keypad or a keyboard, a touch screen, camera, optical scanner, network interface, modem, other known I/O devices or a combination of such I/O devices/interfaces 1108.

The computing device 1100 can further include a communication interface 1110. The communication interface 1110 can include hardware, software, or both. The communication interface 1110 can provide one or more interfaces for communication (such as, for example, packet-based communication) between the computing device and one or more other computing devices (e.g., computing device 1100) or one or more networks. The computing device 1100 can further include a bus 1112. The bus 1112 can comprise hardware, software, or both that couples components of computing device 1100 to each other.

What is claimed is:

1. A method comprising:
encoding, utilizing a transformer neural network, an input feature representation from a digital design depicting one or more design elements and formatted according to an initial aspect ratio, the input feature representation comprising a tokenization of the one or more design elements, a first aspect ratio token indicating the initial aspect ratio, and a second aspect ratio token indicating a target aspect ratio;
transforming, utilizing the transformer neural network, the input feature representation into an output feature representation comprising a modified tokenization of the one or more design elements according to the target aspect ratio; and
generating, from the output feature representation utilizing the transformer neural network, a modified digital design depicting the one or more design elements according to the target aspect ratio.

2. The method of claim 1, wherein encoding the input feature representation comprises:
identifying, utilizing the transformer neural network, the one or more design elements depicted in the digital design;
tokenizing the one or more design elements by generating one or more layout representation tokens corresponding to the one or more design elements; and
combining the one or more layout representation tokens with the first aspect ratio token and the second aspect ratio token.

3. The method of claim 2, wherein generating the one or more layout representation tokens comprises defining a data structure representing a set of characteristics of the one or more design elements.

4. The method of claim 3, wherein defining the data structure comprises generating a 5-tuple defining:
a category characteristic of a design element of the one or more design elements;
a coordinate location characteristic of the design element; and
a set of dimensionality characteristics of the design element.

5. The method of claim 2, wherein combining the one or more layout representation tokens with the first aspect ratio token and the second aspect ratio token comprises concatenating the one or more layout representation tokens with the first aspect ratio token and the second aspect ratio token to form the input feature representation.

6. The method of claim 1, wherein transforming the input feature representation comprises modifying the tokenization of the one or more design elements from encoding characteristics of the one or more design elements according to the initial aspect ratio to encoding the characteristics of the one or more design elements according to the target aspect ratio.

7. The method of claim 1, wherein generating the modified digital design comprises populating the modified digital design with the one or more design elements corresponding to a layout of the digital design according to the target aspect ratio.

8. A system comprising:
a memory component; and
one or more processing devices coupled to the memory component, the one or more processing devices to perform operations comprising:
decomposing a digital design formatted according to an initial aspect ratio into one or more discrete design elements comprising visual components within the digital design;
encoding, using a transformer neural network, the one or more discrete design elements into respective tokenizations;
generating an input feature representation of the digital design by combining the respective tokenizations with an initial aspect ratio token representing the initial aspect ratio and a target aspect ratio token representing a target aspect ratio for the digital design; and
generating, from the input feature representation utilizing the transformer neural network, a modified digital design depicting the one or more discrete design elements according to the target aspect ratio.

9. The system of claim 8, wherein decomposing the digital design comprises:
identifying, utilizing the transformer neural network, the one or more discrete design elements within the digital design;
defining a category characteristic corresponding to a design element among the one or more discrete design elements; and
defining a set of dimensionality characteristics for the design element.

10. The system of claim 9, wherein defining a category value for the design element comprises labeling the design element as an image design element or a text design element.

11. The system of claim 9, wherein defining the set of dimensionality characteristics of the design element comprises:
generating a grid map for the digital design;
identifying, utilizing the grid map of the digital design, a coordinate location characteristic defining a center coordinate of the design element;
identifying, utilizing the grid map of the digital design, a width location characteristic defining a width value of the design element; and
identifying, utilizing the grid map of the digital design, a height location characteristic defining a height value of the design element.

12. The system of claim 8, wherein decomposing the digital design further comprises receiving the digital design and a client device selection specifying the target aspect ratio for the digital design from a client device.

13. The system of claim 8, further comprising providing the modified digital design for display within a graphical user interface on a client device.

14. A non-transitory computer readable medium comprising instructions that, when executed by at least one processor, cause a computing device to perform operations comprising:
encoding, utilizing a transformer neural network, an input feature representation from a digital design depicting one or more design elements by generating attribute tokens from design element attributes of the one or more design elements;
determining a format constraint defining a layout sequence of tokens for an output feature representation corresponding to the input feature representation;
determining, for the output feature representation, a category constraint defining a number of design element attributes corresponding to respective category tokens within the input feature representation; and
transforming, utilizing the transformer neural network, the input feature representation into the output feature representation by modifying and arranging the attribute tokens of the input feature representation according to the format constraint and the category constraint.

15. The non-transitory computer readable medium of claim 14, wherein the operations further comprise training the transformer neural network by:
performing a pretraining process by providing, to the transformer neural network, a first feature representation as input and a second feature representation as output; and
performing a fine-tuning process by providing, to the transformer neural network, a sample input feature representation as input and a sample output feature representation as output.

16. The non-transitory computer readable medium of claim 15, wherein performing the pretraining process comprises providing, to the transformer neural network, a concatenated feature representation comprising the first feature representation and the second feature representation.

17. The non-transitory computer readable medium of claim 15, wherein performing the fine-tuning process comprises training the transformer neural network to transform the sample input feature representation to an aspect ratio of the sample output feature representation.

18. The non-transitory computer readable medium of claim 14, wherein determining the format constraint comprises:
predicting, utilizing the transformer neural network, the layout sequence of tokens for the output feature representation; and
masking one or more noncompliant token sequences from the layout sequence of tokens.

19. The non-transitory computer readable medium of claim 14, wherein determining the category constraint comprises:
identifying, utilizing the transformer neural network, a category characteristic for the one or more design elements;
encoding the respective category tokens for the category characteristic in the input feature representation; and
determining whether the output feature representation includes the number of design element attributes within the input feature representation by comparing a number of category tokens in the output feature representation to a number of category tokens in the input feature representation.

20. The non-transitory computer readable medium of claim 14, wherein the operations further comprise training the transformer neural network by:
generating a sample output feature representation based on a sample input feature representation;
comparing the sample output feature representation to a ground truth output feature representation to determine a loss value; and
modifying parameters of the transformer neural network based on the loss value.
